(19) United States
(12) Patent Application Publication
(10) Pub. No.: US 2022/0037605 A1
(43) Pub. Date: Feb. 3, 2022

(54) ASSEMBLY OF NANOPARTICLES, DISPERSION LIQUID, INK, THIN FILM OF NANOPARTICLES, ORGANIC LIGHT EMITTING DIODE, AND METHOD FOR PRODUCING ASSEMBLY OF NANOPARTICLES

(71) Applicant: AGC Inc., Tokyo (JP)

(72) Inventors: Satoru WATANABE, Tokyo (JP); Yoshitake TODA, Tokyo (JP); Kunio MASUMO, Tokyo (JP); Nao ISHIBASHI, Tokyo (JP); Nobuhiro NAKAMURA, Tokyo (JP); Shimpei MORITA, Tokyo (JP); Hikaru KOBAYASHI, Tokyo (JP)

(73) Assignee: AGC Inc., Tokyo (JP)

(21) Appl. No.: 17/451,675

(22) Filed: Oct. 21, 2021

Related U.S. Application Data
(63) Continuation of application No. PCT/JP2020/017359, filed on Apr. 22, 2020.

(30) Foreign Application Priority Data
Apr. 25, 2019 (JP) 2019-084539

(51) Int. Cl. H01L 51/50; H01L 51/56; H01L 51/00

(52) U.S. Cl. CPC H01L 51/502; H01L 2251/303; H01L 51/0005; H01L 51/56

(57) ABSTRACT

An assembly of nanoparticles includes metal oxide, the nanoparticles including zinc (Zn) and silicon (Si). In addition, the nanoparticles have an atomic ratio of Zn/(Zn+Si) in a range of 0.3 to 0.95. Further, the nanoparticles have an equivalent circular particle diameter in a range of 1 nm to 20 nm.

### CROSS-REFERENCE TO RELATED APPLICATION

The present application is a continuation application filed under 35 U.S.C. 111 (a) claiming benefit under 35 U.S.C. 120 and 365 (c) of PCT International Application No. PCT/JP2020/017359 filed on Apr. 22, 2020 and designating the U.S., which claims priority to Japanese Patent Application No. 2019-084539 filed on Apr. 25, 2019. The entire contents of the foregoing applications are incorporated herein by reference.

### BACKGROUND OF THE INVENTION

### 1. Field of the Invention

The present invention relates to an assembly of nanoparticles, a dispersion liquid, an ink, a thin film of nanoparticles, an organic light emitting diode, and a method of producing an assembly of nanoparticles.

### 2. Description of the Related Art

An organic light emitting diode (OLED) is widely used for displays, backlights, illumination applications, and the like.

According to a certain configuration, the OLED includes a light emitting layer, an anode below the light emitting layer, and a cathode above the light emitting layer.

When a voltage is applied across both electrodes, holes and electrons are injected into the light emitting layer from the respective electrodes. When the holes and the electrons recombine in the light emitting layer, binding energy occurs, and this binding energy excites the light emitting material in the light emitting layer. When the excited light emitting material returns back to a ground state, light is emitted, and accordingly, through this process, light can be emitted to the outside.

In a conventional OLED, in order to enhance the light emitting efficiency, sometimes, a hole injection layer, a hole transport layer, or both are provided between the anode and the light emitting layer, and an electron injection layer, an electron transport layer, or both are provided between the light emitting layer and the cathode.

### CITATION LIST

### Non-Patent Literature

NPL 1: Sebastian Stolz, et al., “Ink-Jet Printed OLEDs for Display Applications” ISSN-L, 1883-2490/25/0639, IDW'18, p. 639-641, 2018

### SUMMARY OF THE INVENTION

### Technical Problem

With the OLED, in order to simplify the production process, it has been suggested that the hole injection layer, the hole transport layer, or both provided on the anode, and the light emitting layer provided thereon are deposited through a printing process (for example, NPL 1).

However, the electron injection layer, the electron transport layer, or both provided on the upper side of the light emitting layer are deposited through an evaporation method. In order to further reduce the production cost and simplify the process, it may be considered to be effective to also deposit the electron injection layer, the electron transport layer, or both through a printing process.

However, in the current circumstances, there has been a problem in that it is difficult to deposit the electron injection layer, the electron transport layer, or both through a printing process. This is because a material that can be deposited through a printing process and that can be applied to the electron injection layer, the electron transport layer, or both, specifically, a candidate material with a low work function and suitable electrical conductivity, have not been sufficiently discovered. In particular, there has been a problem that in a case where an organic electron transport material is formed by a printing method, the underlying light emitting layer may be dissolved, or the interface may be damaged.

Therefore, a material for the electron injection layer, the electron transport layer, or both that can be deposited through a printing process or other low temperature processes is earnestly desired.

In devices other than the OLED, there is a high demand for a technique for depositing, at a low temperature, a material with a low work function and suitable electrical conductivity.

The present invention has been made in view of such background, and it is an object of the present invention to provide a material that has a low work function and suitable electrical conductivity and that can be deposited through a low temperature process. In addition, it is an object of the present invention to provide a dispersion liquid, a thin film, and an OLED, including such a material and to provide a method for producing such a material.

### Solution to Problem

An aspect of one embodiment of the present invention provides an assembly of nanoparticles including metal oxide. The nanoparticles include zinc (Zn) and silicon (Si). The nanoparticles have an atomic ratio of Zn/(Zn+Si) in a range of 0.3 to 0.95. The nanoparticles have an equivalent circular particle diameter in a range of 1 nm to 20 nm.

A second aspect of one embodiment of the present invention provides a dispersion liquid of nanoparticles. The dispersion liquid includes a solvent, and first and second nanoparticles including metal oxide. The first and second nanoparticles include zinc (Zn) and silicon (Si). The first and second nanoparticles have an atomic ratio of Zn/(Zn+Si) in a range of 0.3 to 0.95. The first and second nanoparticles have an equivalent circular particle diameter in a range of 1 nm to 20 nm. The first nanoparticles include a crystal of zinc oxide (ZnO) in which silicon (Si) is dissolved. The second nanoparticles include silicon dioxide (SiO₂) and are in an amorphous state.

A third aspect of one embodiment of the present invention provides an ink including nanoparticles. The ink includes a solvent and a thickener, and first and second nanoparticles including metal oxide. The first and second nanoparticles include zinc (Zn) and silicon (Si). The first and second nanoparticles have an atomic ratio of Zn/(Zn+Si) in a range of 0.3 to 0.95. The first and second nanoparticles have an equivalent circular particle diameter in a range of 1 nm to 20 nm. The first nanoparticles include a crystal of zinc oxide (ZnO) in which Si is dissolved. The second nanoparticles include silicon dioxide (SiO₂) and are in an amorphous state.

A fourth aspect of one embodiment of the present invention provides a thin film including first and second nanoparticles including metal oxide. The first and second nanoparticles include zinc (Zn) and silicon (Si). The first and second nanoparticles have an atomic ratio of Zn/(Zn+Si) in a range of 0.3 to 0.95. The first and second nanoparticles have an equivalent circular particle diameter in a range of 1 nm to 20 nm. The first nanoparticles include a crystal of zinc oxide (ZnO) in which silicon (Si) is dissolved. The second nanoparticles include silicon dioxide (SiO₂) and are in an amorphous state.

A fifth aspect of one embodiment of the present invention provides an organic light emitting diode (OLED). The OLED includes a first electrode, an organic light emitting layer, and an additional layer provided between the first electrode and the organic light emitting layer. The additional layer is constituted by the thin film having the features described above.

A sixth aspect of one embodiment of the present invention provides a method for producing an assembly of nanoparticles including metal oxide. The production method includes: preparing a source material including at least one selected from the group consisting of zinc, silicon, zinc oxide, silicon dioxide, and zinc silicate, the source material including both of a zinc-based component and a silicon-based component; processing the source material with thermal plasma under a first oxygen-containing atmosphere of which a content of oxygen is 0.001% to 90% in volume ratio to vaporize the source material; and solidifying the vaporized source material in a second oxygen-containing atmosphere of which a content of oxygen is 0.00001% to 90% in volume ratio.

### Advantageous Effects of Invention

An aspect of the embodiment of the present invention provides a material that has a low function and suitable electric conductivity and that can be deposited through a low temperature process. Further aspects of the embodiment of the present invention provides a dispersion liquid, a thin film, and an OLED including such a material and also a method for producing such a material.

### BRIEF DESCRIPTION OF THE DRAWINGS

FIG. 1 is a drawing schematically illustrating a flow of a method for producing an assembly of nanoparticles according to an embodiment of the present invention;

FIG. 2 is a drawing schematically illustrating a cross section of an OLED according to the embodiment of the present invention;

FIG. 3 is a drawing schematically illustrating a cross section of an OLED according to another embodiment of the present invention;

FIG. 4 is a graph illustrating a result of X-ray diffraction analysis of powder (powder A) according to the embodiment of the present invention;

FIG. 5 is a graph illustrating the result of Raman spectroscopy analysis of powder (powder A) according to the embodiment of the present invention;

FIG. 6 is a graph illustrating the result of Fourier-transform infrared spectroscopy (FTIR) measurement of a thin film (thin film A) according to the embodiment of the present invention;

FIG. 7 is a graph illustrating the result of measurement of transmittance obtained from a sample (sample AA) according to the embodiment of the present invention;

FIG. 8 is a graph illustrating the result of measurement of voltage-current characteristics obtained from an evaluation laminate (evaluation laminate A) according to the embodiment of the present invention;

FIG. 9 is a graph simultaneously illustrating the result of ultraviolet photoelectron spectroscopy measurement obtained from an evaluation laminate (evaluation laminate B) according to the embodiment of the present invention and the result obtained from a comparison laminate (comparison laminate B);

FIG. 10 is a graph simultaneously illustrating the result of voltage-current characteristics obtained from an evaluation laminate (evaluation laminate C) according to the embodiment of the present invention and the result obtained from a comparison laminate (comparison laminate A);

FIG. 11 is a graph illustrating the result of an ultraviolet photoelectron spectroscopy measurement obtained from evaluation laminates (an evaluation laminate D and an evaluation laminate E) according to the embodiment of the present invention;

FIG. 12 is a graph illustrating the result of measurement of voltage-current density characteristics obtained from an evaluation laminate (evaluation laminate F) according to the embodiment of the present invention; and

FIG. 13 is a graph illustrating the result of ultraviolet photoelectron spectroscopy measurement obtained from an evaluation laminate (evaluation laminate G) according to the embodiment of the present invention.

### DETAILED DESCRIPTION OF THE PREFERRED EMBODIMENTS

Hereinafter, an embodiment of the present invention is described with reference to drawings.

(Nanoparticle According to Embodiment of the Present Invention)

An embodiment of the present invention provides an assembly of nanoparticles comprising metal oxide,

wherein the nanoparticles include zinc (Zn) and silicon (Si),

the nanoparticles have an atomic ratio of Zn/(Zn+Si) in a range of 0.3 to 0.95, and

the nanoparticles have an equivalent circular particle diameter in a range of 1 nm to 20 nm.

In the present application, the term “assembly of nanoparticles” should be understood as having the same meaning as the term “multiple nanoparticles”, and accordingly, the term “assembly of nanoparticles” means an aspect in which two or more nanoparticles are gathered. The nanoparticles included in the assembly of nanoparticles may be in the form of primary particles, the form of secondary particles in which multiple primary particles are gathered, or a mixture of them both.

Also, in the present application, an “equivalent circular particle diameter” of a particle is defined as follows. First, for example, a microscopic image of an evaluation target particle is obtained by using a transmission electron microscope or the like. Next, according to a conventional method using image analysis, a cross-sectional area Sₚ of the particle is measured from the microscopic image. Next, the equivalent circular particle diameter R of the evaluation target particle is obtained according to the following expression (1).

Equivalent circular particle diameter R=2×√(Sₚ/π) Expression (1)

Also, multiple particles may be adopted as the evaluation target, and an average value of the equivalent circular particle diameters R of the evaluation-target particles may be used as an evaluation result. Preferably, the number of particles to be adopted as the evaluation target is 10 or more. More preferably, the number of particles to be adopted as the evaluation target is 100 or more.

In the assembly of nanoparticles according to the embodiment of the present invention, the standard deviation σ of the particle diameter distribution is preferably small. For example, the standard deviation σ of the particle diameter distribution is preferably equal to or less than 3R, more preferably equal to or less than 2R, and still more preferably equal to or less than 1.5R with respect to the equivalent circular particle diameter R of the nanoparticle.

The assembly of nanoparticles according to the embodiment of the present invention is characterized by a low work function and suitable electrical conductivity.

Therefore, for example, the assembly of nanoparticles according to the embodiment of the present invention (hereinafter referred to as an “assembly of ZSO nanoparticles”) can be preferably used as a material for the electron injection layer, the electron transport layer, or both in the OLED.

Each nanoparticle included in the assembly of ZSO nanoparticles has an equivalent circular particle diameter R in a range of 1 nm to 20 nm. Therefore, a dispersion liquid of nanoparticles can be readily prepared by dispersing the assembly of ZSO nanoparticles in a solvent. For example, such a dispersion liquid can be used as ink for a room-temperature process, such as an inkjet printing method.

For example, in a case where an ink in which the assembly of ZSO nanoparticles is dispersed is printed on a light emitting layer of an OLED, the electron injection layer, the electron transport layer, or both can be obtained.

In this manner, by using the assembly of ZSO nanoparticles, the electron injection layer, the electron transport layer, or both in the OLED can be deposited in a low temperature process such as a printing process.

In this case, the assembly of ZSO nanoparticles preferably includes at least two types of nanoparticles, i.e., first nanoparticles and second nanoparticles.

In the assembly of ZSO nanoparticles, any of the first and second nanoparticles include zinc (Zn) and silicon (Si), an atomic ratio of Zn/(Zn+Si) in each of the first and second nanoparticles is in a range of 0.3 to 0.95, and any of the first and second nanoparticles have an equivalent circular particle diameter in a range of 1 nm to 20 nm.

However, the first nanoparticles include a crystal of zinc oxide (ZnO) in which Si is dissolved. In contrast, the second nanoparticles are in an amorphous state. The second nanoparticles may include silicon oxide (SiO₂).

In the assembly of ZSO nanoparticles, the second nanoparticles may occupy 10% by volume to 80% by volume with respect to the entirety of the assembly of ZSO nanoparticles. Preferably, the second nanoparticles occupy 20% by volume to 60% by volume with respect to the entirety of the assembly of ZSO nanoparticles.

In the present application, hereinafter, the nanoparticles included in the assembly of ZSO nanoparticles are also referred to as “ZSO nanoparticles”.

(Production Method of Assembly of Nanoparticles According to Embodiment of the Present Invention)

Next, an example of a method for producing an assembly of nanoparticles according to the embodiment of the present invention is described with reference to drawings.

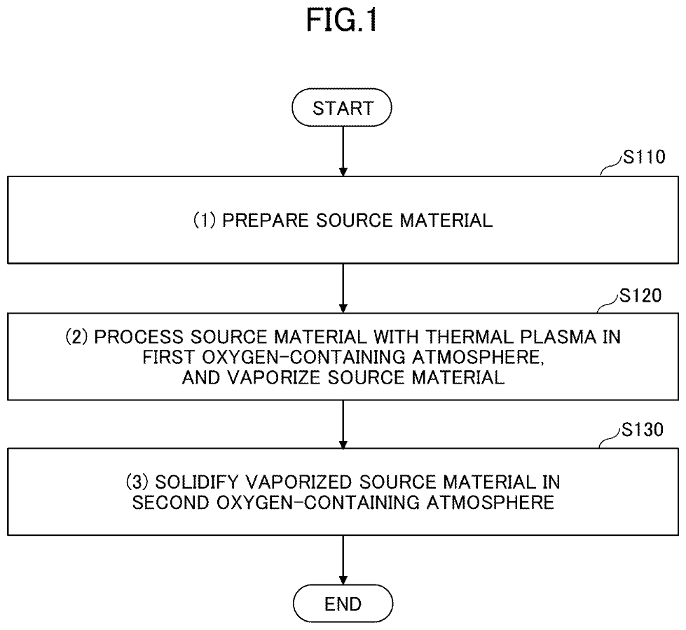

FIG. 1 schematically illustrates a flow of the production method of the assembly of nanoparticles according to the embodiment of the present invention.

As illustrated in FIG. 1, the production method of the assembly of nanoparticles (hereinafter referred to as a “first production method”) according to the embodiment of the present invention includes:

(1) preparing a source material (step S110);

(2) processing the source material with thermal plasma under a first oxygen-containing atmosphere, and vaporizing the source material (step S120); and

(3) solidifying the vaporized source material in a second oxygen-containing atmosphere (step S130).

Hereinafter, each step is described in more detail.

(Step S110)

First, the source material for nanoparticles is prepared.

The source material may be provided in the form of mixed powder or slurry.

In a case where the source material is provided in the form of mixed powder, the mixed powder includes zinc oxide particles and silicon dioxide particles.

Alternatively, the source material may be a mixture of: zinc silicate (Zn₂SiO₄, ZnSiO₃, and the like) particles; and zinc oxide particles or silicon dioxide particles. The mixed powder may be a metal powder including Zn and Si. Examples of metal powders include a metal Zn, a metal Si, an intermetallic compound (alloy) of Zn and Si, and a combination thereof.

For example, the amount of zinc oxide included in the mixed powder may be selected so that an atomic ratio of Zn/(Zn+Si) is in the range of 0.3 to 0.95.

In particular, an atomic ratio of Zn/(Zn+Si) is preferably in a range of 35% to 85%, and more preferably in a range of 50% to 80%.

In contrast, in a case where the source material is provided in the form of slurry, the slurry may be prepared by dispersing the mixed powder in a solvent.

The solvent is not particularly limited. For example, the solvent may be water, alcohol, or both.

(Step S120)

Next, the source material prepared in step S110 is placed in the thermal plasma in the first oxygen-containing atmosphere.

The first oxygen-containing atmosphere may be a mixed atmosphere of argon and oxygen. Also, the temperature of the thermal plasma is, for example, in a range of 9000K to 11000K. The content of oxygen in the mixed atmosphere may be 0.001% to 90% in volume ratio. Preferably, the content of oxygen is 5% to 50%. More preferably, the content of oxygen is 10% to 30%.

In actual production steps, the thermal plasma may be generated in the reaction chamber by controlling atmosphere and applying a high frequency voltage to a coil provided outside or inside of a reaction chamber. Instead of coils, two electrodes contained in the reaction chamber may be used. Next, by supplying the source material to the reaction chamber, the mixed particles in the source material may be vaporized into atmos.

(Step S130)

Next, the vaporized source material is cooled. Accordingly, the vaporized source material is solidified, and the assembly of nanoparticles in the form of powder is produced.

For example, this process may be performed by rapidly cooling and solidifying the vaporized material in the second oxygen-containing atmosphere.

For example, the second oxygen-containing atmosphere may be mixed gas atmosphere of nitrogen and oxygen. The content of oxygen in the mixed atmosphere may be 0.00001% to 90% in volume ratio. Preferably, the content of oxygen is 1% to 70%. More preferably, the content of oxygen is 10% to 50%. As necessary, oxygen does not have to be contained, and only nitrogen may be adopted as atmosphere. In this manner, the conductivity of the assembly of nanoparticles can be controlled by adjusting the content of oxygen in the mixed gas atmosphere. Further, when the content of oxygen is 10% to 30%, crystal growth and generation of coarse particle can be alleviated, and the particle diameters of the ZSO nanoparticles can be reduced, which are preferable. More preferably, the content of oxygen is 20% to 25%.

After step S130, the assembly of nanoparticles is obtained.

However, after step S130, in addition, additional steps such as a size reduction step, a classification step, or both of these steps may be performed.

In particular, the assembly of nanoparticles obtained after step S130 may include the primary particles and the secondary particles. However, when the size reduction step is performed, the secondary particles are likely to be separated into the primary particles, and an assembly of nanoparticles mainly including the primary particles can be obtained.

Examples of specific size reduction processing include methods of mechanically pulverizing the assembly of nanoparticles by using planetary mills, ball mills, jet mills, and the like. By performing such a size reduction step, the secondary particles diameter included in the assembly of nanoparticles can be reduced to 1 μm or less.

Further, the bead crushing processing may be performed on the assembly of nanoparticles of which sizes have been reduced. When the bead crushing is performed by mixing the assembly of nanoparticles, of which sizes have been reduced, with an organic solvent, smaller secondary particles, of which secondary particle diameters are, for example, 100 nm or less, can be obtained. In such bead crushing processing, for example, zirconium oxide beads can be used.

In the assembly of nanoparticles produced by the first production method, a nanoparticle includes zinc (Zn) and silicon (Si), any given nanoparticle has an atomic ratio of Zn/(Zn+Si) in a range of 0.3 to 0.95, and any given nanoparticle has an equivalent circular particle diameter in a range of 1 nm to 20 nm.

Also, the assembly of nanoparticles may include at least two types of nanoparticle, i.e., the first nanoparticles and the second nanoparticles having the features as described above.

The production method of the assembly of nanoparticles is merely an example, and the assembly of nanoparticles may be produced by other production methods. For example, the production method using the thermal plasma as described above is a type of a “vapor production method”, but the assembly of nanoparticles may be produced by other vapor production methods such as a spray pyrolysis method. Alternatively, the assembly of nanoparticles may be produced by production methods other than the vapor production method, for example, a “liquid phase production method”.

For example, the “liquid phase production method” includes a method for producing an assembly of nanoparticles by precipitating a solid from a solution prepared by dissolving the mixed power in an acid or the like. The liquid phase production method may be a sol-gel method, a coprecipitation method, a liquid phase reduction method, a liquid phase plasma method, an alkoxide method, a hydrothermal synthesis method, a supercritical hydrothermal synthesis method, and the like. Surface treatment such as powder atomic layer deposition (ALD) coating, powder plasma coating, and sol-gel coating may be applied to each nanoparticle.

### Example of Application of Assembly of Nanoparticles According to Embodiment of the Present Invention

Next, an example of application of an assembly of nanoparticles according to the embodiment of the present invention is described.

(Thin Film)

For example, an assembly of nanoparticles according to the embodiment of the present invention, i.e., an assembly of ZSO nanoparticles, can be used in the form of a thin film.

For example, such a thin film is formed by applying slurry, paste, or ink, in which the ZSO nanoparticles are dispersed described later, onto a member, forming a coating film, and thereafter, applying thermal treatment to the member on which the coating film is formed.

Examples of methods for applying slurry, paste, or ink include methods such as spray coating, die coating, roll coating, dip coating, curtain coating, spin coating, gravure coating, screen printing, nozzle printing, flexographic printing, offset printing, xerography, microcontact printing, inkjet printing, and the like. In particular, the inkjet printing method is preferable from the viewpoint of simplicity.

The thermal treatment temperature is preferably at a temperature at which an organic matter included in the coating film is likely to volatilize, for example, in a range of 50 to 300° C. When the thermal treatment temperature is in a range of 80 to 150° C., an organic matter sufficiently evaporates, whereas deterioration of other organic layers such as a light emitting layer can be prevented, which is preferable. The length of the thermal treatment is preferably about 10 minutes. With the above thermal treatment, further, drying under reduced pressure may be performed in combination.

After the thermal treatment, a thin film constituted by the ZSO nanoparticles is formed.

For example, the thin film may be the electron injection layer, the electron transport layer, or both of the OLED described later. In this case, the electron injection layer, the electron transport layer, or both, of which the work function is significantly low, can be obtained.

However, the thin film including the ZSO nanoparticles can be used for various devices other than the electron injection layer, the electron transport layer, or both of the OLED. For example, the thin film including the assembly of ZSO nanoparticles can be used for a layer or the like constituting a portion of a photovoltaic cell, a thin film transistor (TFT), a quantum dot light emitting diode (QD-LED), a perovskite light emitting device, or the like.

(Dispersion Liquid)

For example, the assembly of nanoparticles according to the embodiment of the present invention, i.e., the assembly of ZSO nanoparticles, can be provided in the form of a dispersion liquid.

The dispersion liquid can be prepared by dispersing the assembly of ZSO nanoparticles in a solvent.

When the polar solvent is used as the solvent, an underlying organic layer such as a light emitting layer is less likely to be dissolved, and the damage to the interface can be reduced, which is preferable. Examples of polar solvents include water, alcohols, glycols, ethers, or a combination thereof.

Examples of suitable alcohols, glycols, or ethers may include methanol, ethanol, 1-propanol, 2-propanol, 1-butanol, 2-butanol, ethylene glycol, propylene glycol, ethylene glycol monomethyl ether, ethylene glycol monoethyl ether, ethylene glycol monobutyl ether, ethylene glycol isopropyl ether, propylene glycol monomethyl ether, propylene glycol monoethyl ether, propylene glycol isopropyl ether, pentyl alcohol, 1-hexanol, 1-octanol, 1-pentanol, tert-pentyl alcohol, N-methylformamide, N-methylpyrrolidone, dimethylsulfoxide, and the like. Alternatively, a fluorinated alcohol-based solvent or a glycol dialkyl ether-based solvent may be used as the solvent.

These solvents may be used alone or in combination.

These solvents are insoluble in the light emitting layer constituted by an organic matter in an OLED. Therefore, in a case where the electron injection layer, the electron transport layer, or both, including nanoparticles, are formed on the light emitting layer of the OLED by using the dispersion liquid including these solvents, the damage to the interface can be reduced. In particular, glycols, which are dihydric alcohols, are highly polar, which is preferable.

However, in a case where the dispersion liquid including the ZSO nanoparticles is used for other purposes, for example, a non-polar solvent such as water, acetone, benzene, toluene, xylene, hexane, or a combination thereof can also be used as the solvent.

For example, the assembly of ZSO nanoparticles obtained after step S130 in the above first production method can be directly used as the nanoparticle dispersed in the dispersion liquid. Alternatively, after step S130, the size reduction processing described above may be further performed, and the resulting assembly of ZSO nanoparticles may be used.

In the latter case, a dispersion liquid in which mainly primary particles are dispersed can be prepared.

In the dispersion liquid, the amount of ZSO nanoparticles is, for example, in a range of 0.01 mass % to 50 mass %, and the amount of the solvent may be, for example, in a range of 50 mass % to 99.9 mass %.

The assembly of ZSO nanoparticles may be mixed with an organic solvent or a vehicle instead of being made into a dispersion liquid, so that the assembly of ZSO nanoparticles is made into the form of slurry or paste.

The ink may further contain additives such as a dispersant, a pH regulator, a surfactant, a thickener, or a combination thereof. These additives are described later.

(Ink)

The assembly of ZSO nanoparticles may be prepared in the form of ink, which is a form of the dispersion liquid described above.

The ink may be prepared by dispersing the assembly of ZSO nanoparticles in the ink solvent, or may be adjusted by adding a desired ink component to the dispersion liquid. Solvents listed as the solvents for the dispersion liquid above can be used as the ink solvent.

The ink solvent is preferably a solvent having a boiling point of 120° C. or less at which the solvent is readily volatilized by the thermal treatment. Examples of ink solvents include 1-propanol, 2-propanol, 1-butanol, 2-butanol, tert-pentyl alcohol, and propylene glycol monomethyl ether.

In particular, in a case where the solvent of the ink is used for inkjet printing, the boiling point is preferably 180° C. or more. When the boiling point is configured to be 180° C. or more, clogging of the inkjet head due to drying of the solvent can be alleviated. Examples of such ink solvents include ethylene glycol and propylene glycol.

These ink solvents are characterized by a high dispersibility of the ZSO nanoparticles.

In a case where the electron injection layer, the electron transport layer, or both, including the ZSO nanoparticles, are formed on the organic light emitting layer of the OLED by using the ink including these ink solvents, the damage to the organic light emitting layer can be reduced.

The ink (and the dispersion liquid described above) may further contain additives such as a dispersant, a pH regulator, a surfactant, a thickener, or a combination thereof.

Polymer type dispersants, surfactant type dispersants, inorganic type dispersants, and the like can be used as the dispersant. Among these dispersants, polycarboxylic acid-based dispersants, naphthalene sulfonic acid formalin condensation-based dispersants, polycarboxylic acid partially alkyl ester-based dispersants, and alkyl sulfonic acid-based dispersants can be used as the anion-based dispersant. Polyalkylene polyamine-based, polyimine-based, quaternary ammonium-based, and alkyl-polyamine-based dispersants can be used as the cation-based dispersant.

Specific examples of dispersants include sodium pyrophosphate (Napp), sodium hexametaphosphate (NaHMP), trisodium phosphate (TSP), lower alcohol, acetone, polyoxyethylene alkyl ether, acetylacetone, ammonium polyacrylate, polyethyleneimine (PEI), polyethyleneimine ethoxylates (PEIE), and linear alkylbenzene, and the like.

A hydrocarbon compound, a silicone compound, or a perfluoro compound can be used as the surfactant.

The thickener includes propylene glycol, terpineol, and cellulosic thickeners such as, for example, ethyl cellulose, carboxymethyl cellulose, and ethyl cellulose. In addition, the additive may include a transparent conductor (such as indium tin oxide, aluminum-doped zinc oxide (AZO), carbon black, or a combination thereof) for adjusting the conductivity of the ink.

For example, the additive may be contained in the ink at a concentration of 10 mass % or less.

The viscosity of the ink is preferably 1 to 50 mPa·s (CP). In particular, when used for inkjet printing, the viscosity of the ink is preferably 5 to 20 mPa·s (CP). Furthermore, in particular, when used for inkjet printing, the viscosity of the ink is more preferably 8 to 15 mPa·s (CP). In particular, when used for inkjet printing, it is preferable to adjust the ink composition so that the ink exhibits the viscosity in a temperature range of 30° C. to 80° C. by using a head with a heating mechanism.

The surface tension of the ink is preferably 10 to 75 mN/m. In particular, when used for inkjet printing, the surface tension of the ink is preferably 15 to 50 mN/m. Furthermore, in particular, when used for inkjet printing, the surface tension of the ink is more preferably 25 to 40 mN/m. The surface tension of the ink can be adjusted may be adjusted by applying the surfactant is applied to the ink.

The ink solvent preferably has a low moisture content, and therefore, ink solvent is preferably used after being dehydrated. The method of dehydration is not particularly limited, but molecular sieve, anhydrous sodium sulfate, calcium hydroxide, or a combination thereof can be used. The water content of the ink solvent is preferably 0.1 mass % or less.

Furthermore, the ink (and the dispersion liquid described above) may contain a complex of alkaline metal, a salt of alkaline metal, a complex of alkaline earth metal, or a salt of alkaline earth metal.

By using such an ink, the electron injection layer, the electron transport layer, or both, containing complex or salt of alkaline metal or alkaline earth metal, can be formed. Because the electron injection layer, the electron transport layer, or both includes the complex or salt of alkaline metal and alkaline earth metal, the efficiency of electron injection can be further improved.

The complex or salt of alkaline metal and alkaline earth metal is preferably soluble in the above ink solvent. Examples of the alkaline metal include lithium, sodium, potassium, rubidium, and cesium. Examples of alkaline earth metals include magnesium, calcium, strontium, and barium. Examples of the complex include a β-diketone complex, and examples of salts include alkoxides, phenoxides, carboxylates, carbonates, and hydroxides.

Specific examples of the complex or salt of alkaline metal and alkaline earth metal include sodium acetylacetonato, cesium acetylacetonato, calcium bisacetylacetonato, barium bisacetylacetonato, sodium methoxyde, sodium phenoxide, sodium tert-butoxide, sodium tert-pentoxide, sodium acetate, sodium citrate, cesium carbonate, cesium acetate, sodium hydroxide, and cesium hydroxide, and the like.

(Organic Light Emitting Diode According to Embodiment of the Present Invention)

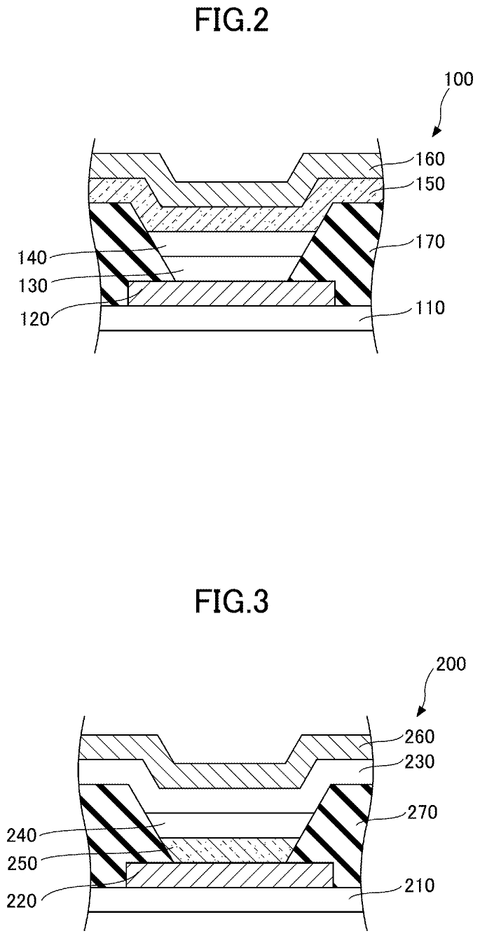

Next, an example of an organic light emitting diode (OLED) according to the embodiment of the present invention is described with reference to FIG. 2.

FIG. 2 schematically illustrates a cross section of an OLED (hereinafter referred to as a “first OLED”) according to the embodiment of the present invention.

As illustrated in FIG. 2, the first OLED 100 includes a substrate 110, a bottom electrode (anode) 120, a hole injection layer and hole transport layer 130, a light emitting layer 140, an additional layer 150, an upper electrode (anode) 160, and an insulating layer 170. The hole injection layer and hole transport layer 130 may include one of a hole injection layer or a hole transport layer, or may include both of the hole injection layer and the hole transport layer.

In a case where the substrate 110 and the bottom electrode 120 are made of a transparent material in the first OLED 100, the first OLED 100 is of a bottom emission type in which the side of substrate 110 is the light extraction surface. In a case where the upper electrode 160 is made of a transparent material or a semi-transparent material and the lower side of the bottom electrode 120 is made of a reflection layer in the first OLED 100, the first OLED 100 is of a top emission type in which the side of the upper electrode 160 is the light extraction surface.

The substrate 110 is configured to support the layers provided in the upper portion.

In the case where the side of substrate 110 is the light extraction surface (the bottom emission type), the bottom electrode 120 is made of, for example, a conductive metal oxide such as indium tin oxide (ITO). For example, the upper electrode 160 is made of a metal or a semiconductor. The hole injection layer and hole transport layer 130 is constituted by a hole transporting compound. The hole transporting compound is preferably a compound with an ionization potential of 4.5 eV to 6.0 eV from the viewpoint of charge injection barrier from the anode to the hole injection layer.

Examples of hole transporting compounds include aromatic amine-based compounds, phthalocyanine-based compound, porphyrin-based compounds, oligothiophene-based compounds, polythiophene-based compounds, benzylphenyl-based compounds, compounds in which tertiary amines are linked with a fluorene group, hydrazone-based compounds, silazane-based compounds, quinacridone-based compounds, and the like. Examples include: triphenylamine derivatives; N,N′-bis(1-naphthyl)-N,N′-diphenyl-1,1′-biphenyl-4,4′-diamine (NPD); N,N′-diphenyl-N,N′-bis[N-phenyl-N-(2-naphthyl)-4′-aminobiphenyl-4-yl]-1,1′-biphenyl-4,4′-diamine (NPTE); 1,1-bis[(Di-4-trilamino)phenyl]Cyclohexane (HTM2); and N,N′-diphenyl-N,N′-bis(3-methylphenyl)-1,1′-diphenyl-4,4′-diamine (TPD).

Among the above compounds listed as examples, aromatic amine compounds are preferable, and aromatic tertiary amine compounds are particularly preferable from the viewpoint of amorphous property and visible light transmission. In this case, the aromatic tertiary amine compounds are compounds having an aromatic tertiary amine structure, and also includes compounds having a group derived from an aromatic tertiary amine.

The types of aromatic tertiary amine compounds are not particularly limited, but it is preferable to use a polymer compound with a weight average molecular weight of 1000 or more and 1000000 or less (a polymerized compound in which repeating units are connected) because it is easy to obtain uniform light emission due to the surface smoothing effect.

For example, the light emitting layer 140 is constituted by an organic matter that emits light in, e.g., red, green, blue, or a combination thereof.

The light emitting layer is a functional layer that has the function of emitting light (including visible light). The light emitting layer is usually constituted by an organic matter that emits light of mainly through at least one of fluorescence and phosphorescence, or constituted by an organic matter and a dopant that assists the matter. For example, the dopant is applied to improve the light emitting efficiency and to change the wavelength of the emitted light. The organic matter may be either a low-molecular compound or a high-molecular compound. For example, the thickness of the light emitting layer may be about 2 nm to 200 nm.

Examples of organic matters that emit light mainly through either fluorescence or phosphorescence include dye-based materials, metal complex-based materials, and high molecule-based materials described below. Quantum dots such as: for example, II-VI group-based inorganic matters such as CdSe, CDS, and the like; III-V group-based inorganic matters such as InP, InGaP, GaN, InGaN, and the like; and perovskite-based inorganic matters such as CsPbX3 (X=Cl/Br/I) and the like may be used as the light emitting layer.

(Pigment-Based Material)

Examples of dye-based materials include cyclopendamine derivatives, tetraphenylbutadiene derivative compounds, triphenylamine derivatives, oxadiazole derivatives, pyrazoloquinoline derivatives, distyrylbenzene derivatives, distyrylarylene derivatives, pyrrole derivatives, thiophene cyclic compounds, pyridine cyclic compounds, perinone derivatives, perylene derivatives, oligothiophene derivatives, oxaziazole dimers, pyrazoline dimers, quinacridone derivatives, coumarin derivatives, and the like.

(Metal Complex-Based Materials)

Examples of metal complex-based materials include rare earth metals such as Tb, Eu, Dy, and the like, or metal complexes having Al, Zn, Be, Ir, Pt, or the like as a central metal and having oxadiazole, thiadiazole, phenylpyridine, phenylbenzimidazole, quinoline structure, or the like as a ligand, and examples include: metal complex with light emission from triplet excited state such as iridium complex and platinum complex; aluminum quinolinol complex; benzoquinolinol beryllium complex; benzoxazolyl zinc complex; benzothiazole zinc complex; azomethyl zinc complex; porphyrin zinc complex; phenanthroline europium complex; and the like.

(High Molecule-Based Materials)

Examples of high molecule-based materials include polyparaphenylene vinylene derivatives, polythiophene derivatives, polyparaphenylene derivatives, polysilane derivatives, polyacetylene derivatives, polyfluorene derivatives, polyvinylcarbazole derivative, materials obtained by polymerizing a dye-based materials and a metal complex-based light emitting material, and the like.

(Materials of Dopants)

Examples of materials of dopants include perylene derivatives, coumarin derivatives, rubrene derivatives, quinacridone derivatives, squalium derivatives, porphyrin derivatives, styryl dyes, tetracene derivatives, pyrazolone derivatives, decacyclene, phenoxazone, and the like.

For example, the insulating layer 170 is constituted by a photosensitive resin such as fluororesins and polyimide resins.

For example, the hole injection layer and hole transport layer 130, the light emitting layer 140, or both can be formed through a printing process.

In the first OLED 100, the technical specifications of the layer other than the additional layer 150 are known to those skilled in the art. Therefore, it is not described here anymore.

Hereinafter, in the first OLED 100, the additional layer 150 includes first and second nanoparticles including metal oxide,

wherein the first and second nanoparticles include zinc (Zn) and silicon (Si) at an atomic ratio of Zn/(Zn+Si) in a range of 0.3 to 0.95,

the first and second nanoparticles have an equivalent circular particle diameter in a range of 1 nm to 20 nm;

the first nanoparticles include a crystal of zinc oxide (ZnO) in which Si is dissolved, and

the second nanoparticles include silicon dioxide (SiO₂) and are in an amorphous state.

The additional layer 150 has a relatively low work function and suitable electrical conductivity. The additional layer 150 has a relatively low work function and suitable electrical conductivity. For example, the work function of the additional layer 150 is 3.5 eV or less. The conductivity of the additional layer 150 is, for example, 10⁻⁸ Scm⁻¹ or more, and is, for example, 10⁻⁵ Scm⁻¹ or more.

Therefore, the additional layer 150 can function as the electron injection layer, the electron transport layer, or both.

The presence of the first nanoparticles and the second nanoparticles can be considered to be the reason why the additional layer 150 exhibits a high conductivity and a low work function.

Specifically, the first nanoparticles contained in the additional layer 150 include crystals of zinc oxide in which Si is dissolved, and this is considered to contribute to the conductivity of the additional layer 150. In addition, the second nanoparticles contained in the additional layer 150 include amorphous silicon dioxide, and this is considered to contribute to the reduction of the work function of the additional layer 150.

Furthermore, the additional layer 150 can be deposited using a low temperature process such as a printing process. That is, the additional layer 150 can be formed on the light emitting layer 140 by preparing the dispersion liquid or the like as described above and performing a printing process using the dispersion liquid.

For example, an inkjet printing method, a screen printing method, or the like can be used as the printing process. In particular, when the additional layer 150 is provided by the printing process, the thickness can be readily controlled as compared with the case where the additional layer 150 is formed by a conventional evaporation method. Therefore, by changing the thickness of the electron transport layer, the optical path length can be adjusted for each pixel.

In the first OLED 100, an equivalent circular particle diameter R of a nanoparticle included in the additional layer 150 is in a range of 1 nm to 20 nm. When the equivalent circular particle diameter R of a nanoparticle is configured to be 20 nm or less, the additional layer 150 can be printed using the inkjet printing method.

In this manner, in the first OLED 100, the layers from the hole injection layer and hole transport layer 130 to the additional layer 150 can be formed through a printing process.

In this case, the necessity for conventional vapor deposition equipment to form the electron injection layer, the electron transport layer, or both is eliminated, and the equipment cost for the production can be reduced. In addition, the efficiency for using materials can be significantly improved. Therefore, the first OLED 100 can be readily produced at a relatively low cost.

In the conventional configuration, when an upper electrode is provided on an organic-based electron injection layer, an electron transport layer, or both, the electron injection layer, the electron transport layer, or both may be damaged by heat. Therefore, there is a problem that it is difficult to deposit the upper electrode 160 by a high-temperature process such as sputtering.

However, in the first OLED 100, the additional layer 150 includes the first and second nanoparticles including metal oxide having the features described above. Therefore, the upper electrode 160 provided on the additional layer 150 can be deposited even by, for example, a heat generating process such as sputtering.

Furthermore, because the upper electrode 160 can be formed by sputtering, the area of the OLED can be increased.

(Organic Light Emitting Diode According to Another Embodiment of the Present Invention)

Next, an example of an OLED according to another embodiment of the present invention is described with reference to FIG. 3.

FIG. 3 schematically illustrates a cross section of an OLED (hereinafter referred to as a “second OLED”) according to another embodiment of the present invention.

As illustrated in FIG. 3, a second OLED 200 has a configuration similar to the first OLED 100 illustrated in FIG. 2. However, certain structures of the second OLED 200 are inverted in comparison to the first OLED 100.

Specifically, the second OLED 200 includes a substrate 210, a bottom electrode 220, an additional layer 250, a light emitting layer 240, a hole injection layer and hole transport layer 230, an upper electrode 260, and an insulating layer 270. The bottom electrode 220 functions as a cathode, and the upper electrode 260 functions as an anode. The hole injection layer and hole transport layer 230 may include one of a hole injection layer or a hole transport layer, or may include both of the hole injection layer and the hole transport layer.

In this case, in the second OLED 200, the additional layer 250 includes first and second nanoparticles including metal oxide,

wherein the first and second nanoparticles include zinc (Zn) and silicon (Si) at an atomic ratio of Zn/(Zn+Si) in a range of 0.3 to 0.95,

the first and second nanoparticles have an equivalent circular particle diameter in a range of 1 nm to 20 nm;

the first nanoparticles include a crystal of zinc oxide (ZnO) in which Si is dissolved, and

the second nanoparticles include silicon dioxide (SiO₂) and are in an amorphous state.

It is clear to those skilled in the art that the same effects as those of the first OLED 100 described above can be obtained with the second OLED 200 having such a configuration.

For example, the additional layer 250 includes a relatively low work function and suitable electrical conductivity. For example, the work function of the additional layer 250 is 3.5 eV or less. The conductivity of the additional layer 250 is, for example, 10⁻⁸ Scm⁻¹ or more, and is, for example, 10⁻⁵ Scm⁻¹ or more. Therefore, the additional layer 250 can function as the electron injection layer, the electron transport layer, or both.

The additional layer 250 can be deposited using a low temperature process such as a printing process. Therefore, the necessity for conventional vapor deposition equipment for forming the electron injection layer, the electron transport layer, or both is eliminated, and the equipment cost can be reduced. In addition, the efficiency for using the material can be significantly improved. Therefore, the second OLED 200 can be readily produced at a relatively low cost.

### EXAMPLES

Hereinafter, Examples of the present invention are described.

### Example 1

(Production of Assembly of ZSO Nanoparticles)

According to the first production method described above, an assembly of ZSO nanoparticles was produced.

The source material was a slurry including zinc oxide particles and silicon dioxide particles. The slurry was prepared by dispersing, in alcohol, mixed powder that was obtained by mixing zinc oxide particles and silicon dioxide particles to attain a molar ratio of 60:40.

Next, the slurry serving as the source material was put into the thermal plasma generated in the reaction chamber. The thermal plasma was generated by applying a high frequency voltage across electrodes in the reaction chamber under a mixed atmosphere of argon and oxygen (Ar:O₂=80:20). The temperature of the thermal plasma was about 10000K.

The slurry serving as the source material was converted into plasma by the thermal plasma made into a gas phase. Thereafter, a mixed gas (N₂:O₂=75:25) of nitrogen and oxygen at room temperature was supplied to this gas phase, and the gas phase was rapidly cooled.

As a result, a powdery material (hereinafter referred to as “powder A”) was produced.

(Preparation of Dispersion Liquid)

Next, a dispersion liquid was prepared using the powder A.

Specifically, 0.5 g of powder A, as described above, was added to 19.5 g of 1-propanol. In addition, 150 g of zirconia oxide beads with 0.5 mmφ serving as a crushing mill were mixed to prepare a mixture. Next, the mixture was placed in a polyethylene container and rotated and pulverized for 96 hours. The rotation speed was 280 rpm.

As a result, a dispersion liquid containing ZSO nanoparticle at 2.5 mass % and 1-propanol at 97.5 mass % (hereinafter referred to as a “dispersion liquid A”) was obtained.

(Formation of Thin Film)

Next, a thin film was formed on a transparent substrate by a spin coating method using the dispersion liquid A.

The rotation speed of the transparent substrate during the deposition was 1800 rpm or 4000 rpm. After the spin coating, a transparent substrate was placed on a hot plate at a 150° C. to perform thermal treatment of the coating.

As a result, a transparent substrate with a thin film (hereinafter referred to as a “sample A with a thin film A”) was obtained.

(Evaluation)

(Structure Evaluation)

When the specific surface area was measured using the powder A described above, the specific surface area of the powder A was found to be 87.2 m²g⁻¹. The particle diameter of the powder A derived from the specific surface area was 12.1 nm.

Next, fluorescent X-ray analysis of the powder A was performed.

As a result, the cation ratio of the powder A was found to be Zn:Si=75.0:25.0 in molar ratio.

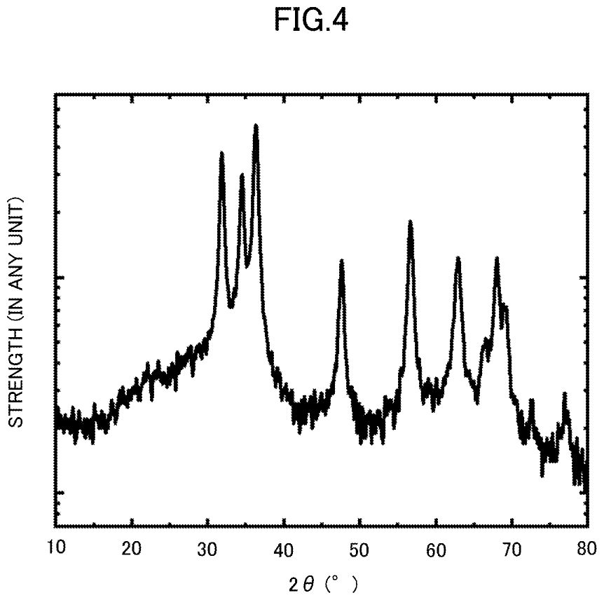

In addition, the X-ray diffraction analysis of the powder A was performed. The result is shown in FIG. 4.

As illustrated in FIG. 4, in the X-ray pattern of the powder A, peaks corresponding to ZnO crystal (wurtzite type) and halo derived from amorphous structure were observed.

It was found from the above that the powder A contained a ZnO crystal phase and an amorphous phase.

(Raman Spectroscopy Analysis)

Next, a microscopic Raman spectroscopy analysis of the powder A was performed. For the measurement, Nicolet Almega manufactured by Thermo Fisher Scientific Inc. was used.

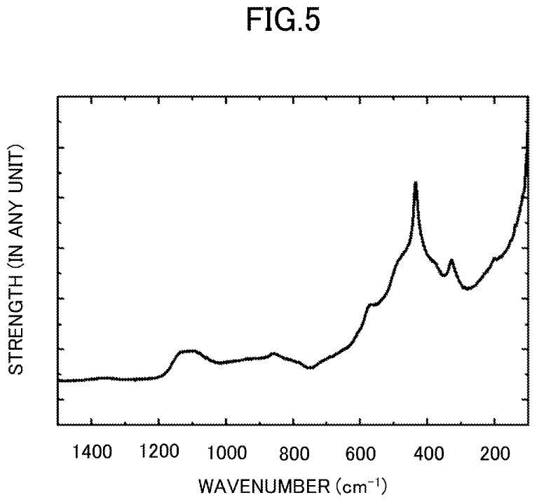

FIG. 5 illustrates the Raman spectrum of the powder A. A sharp Raman scattering peak is observed near a wavenumber of 400 cm⁻¹. This is also observed with pure zinc oxide crystal (wurtzite type), and this indicates that at least a portion of the powder A has a crystalline structure of zinc oxide.

In addition, wide Raman scattering peaks were observed at around wavenumbers of 300 to 600 and 1000 to 1100 cm⁻¹. These peaks were also observed with silica glass or glass containing silicon dioxide and in the amorphous phase.

In contrast, such scattering peaks were not observed with ZnO crystal and Zn₂SiO₄ crystal, and therefore, the Raman scattering peaks were caused due to the tetrahedron or Si—O—Si bond of linked SiO₄. In addition, these Raman scattering peaks were wider than those of crystal compounds of various silicon dioxide, and therefore, it was found that the powder A contained an amorphous phase containing silicon dioxide (SiO₂).

It was found from the above that the powder A contained a crystal phase having a ZnO crystal structure and an amorphous phase containing silicon dioxide (SiO₂).

The Fourier-transform infrared spectroscopy (FTIR) measurement of the thin film A was carried out using the above-described sample A. For the measurement, VERTEX-70v manufactured by Bruker Corporation was used.

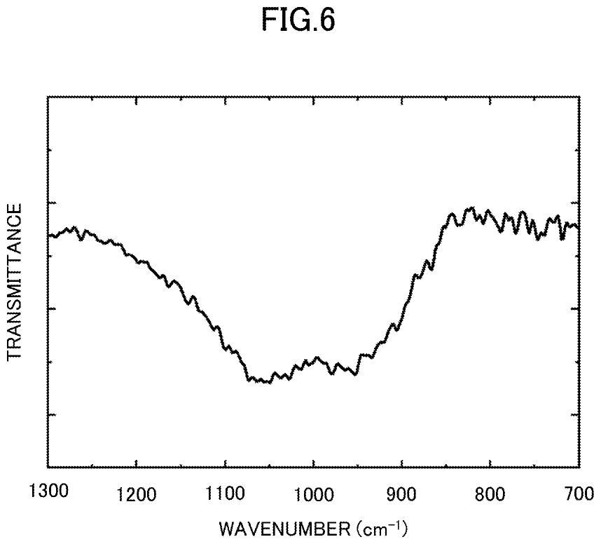

FIG. 6 illustrates an obtained infrared (IR) spectrum.

As illustrated in FIG. 6, in the IR spectrum, an absorption band was observed at around wavenumbers of 1000 to 1100 cm⁻¹.

The absorption band at this position was not observed with standard ZnO crystal and Zn₂SiO₄ crystal. In contrast, the connected SiO₄ tetrahedrons are known to exhibit absorption at this position.

Next, transmission electron microscope (TEM) observation of the powder A was performed.

From the TEM observation image, an equivalent circular particle diameter R was calculated according to the above method. As a result, it was found that the equivalent circular particle diameter R of each particle contained the powder A was about 10 nm.

Next, with energy dispersive X-ray spectroscopy (EDX), composition analysis and electron diffraction of some of the particles contained in the powder A were performed.

As a result, it was determined that at least two types of particles, i.e., first particles and second particles, were present in the powder A in a mixed manner.

Among them, it was found that the first particles included a ZnO crystal structure (wurtzite type) and further contained Si. It was also found that the second particles had an amorphous structure and contained more Si than the first particles.

When composition analysis was performed on any given first particle, Zn:Si was 93:7. Moreover, when composition analysis was performed on any given second particle, Zn:Si was 50:50.

In an EDX mapping image, the abundance rate of the second particles was in a range of 40% by volume to 60% by volume.

(Evaluation of Physical Properties)

Next, a sample for physical properties evaluation was prepared according to the following method, and each physical property value was measured.

(Transmittance)

A sample for transmittance measurement (hereinafter referred to as a “sample AA”) was prepared according to the following method.

Using the dispersion liquid A prepared by the above method, a thin film was prepared on a silica glass substrate by a spin coating method. The thickness of the thin film was 140 nm.

The transmittance was measured using the obtained sample AA.

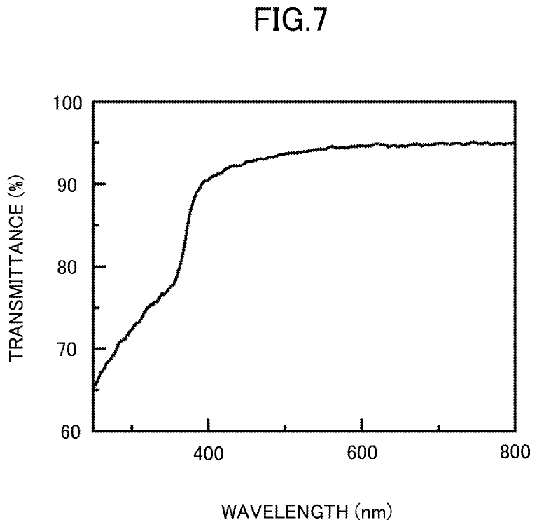

FIG. 7 illustrates a measurement result of transmittance obtained with the sample AA.

As illustrated in FIG. 7, it was found that the sample AA had a sufficiently high visible light transmittance. In this manner, it was found that, in a case where the dispersion liquid A is used, a sufficiently transparent thin film can be deposited.

(Conductivity)

Molybdenum wiring with a width of 0.5 mm (hereinafter referred to as a “first Mo wiring”) was formed on the glass substrate. The first Mo wiring was deposited through sputtering using a metal mask.

Next, using the dispersion liquid A described above, a coating film was formed on the glass substrate and the first Mo wiring by the spin coating method. Thereafter, the coating film was baked at 150° C. to form a thin film. The thickness of the thin film was 130 nm.

Furthermore, a second Mo wiring was formed thereon by sputtering.

As a result, a four-layer laminate including a glass substrate, a first Mo wiring, a thin film, and a second Mo wiring was produced. The obtained laminate is hereinafter referred to as an “evaluation laminate A”. The evaluation laminate A has an area of 0.5×0.5 mm when viewed from above, and each constituent element has a similar size of area.

For comparison, a laminate was prepared according to a similar method using a commercially available dispersion liquid (manufactured by Avantama AG) in which ZnO nanoparticles were dispersed. The obtained laminate is hereinafter referred to as a “comparison laminate A”.

Next, using the evaluation laminate A, the voltage-current characteristics were measured. Specifically, a voltage was applied across a first Mo wiring and a second Mo wiring of the evaluation laminate A, and the generated current was measured.

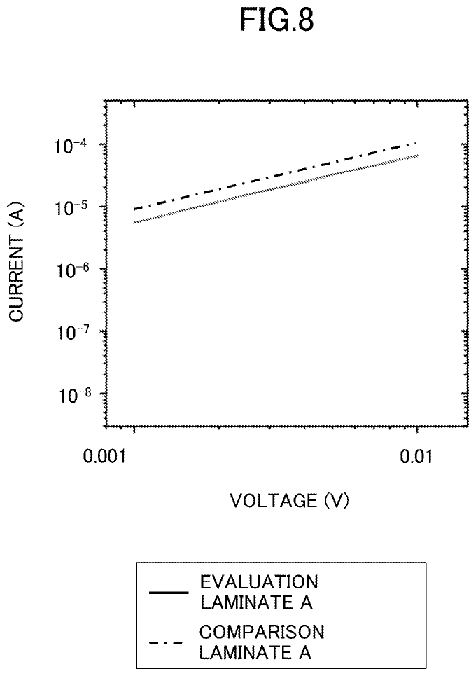

FIG. 8 illustrates a measurement result. In FIG. 8, the horizontal axis indicates a voltage, and the vertical axis indicates a current. For comparison, FIG. 8 also illustrates a result obtained with the comparison laminate A.

As illustrated in FIG. 8, in the evaluation laminate A, a linear relationship was obtained between the applied voltage and the measured current. Therefore, it was determined that the thin film of the evaluation laminate A formed an ohmic contact with each of the Mo electrodes.

In the evaluation laminate A, the measured voltage-current relationship exhibited almost the same feature as the voltage-current relationship of the comparison laminate, and it was found that the thin film contained in the evaluation laminate A exhibited high conductivity.

When the conductivity of the thin film of evaluation laminate A was calculated from the obtained result, the conductivity was found to be 6.1×10⁻⁵ This conductivity can be said to be a sufficiently preferable value, considering an application of the thin film to the electron injection layer, the electron transport layer, or both of the OLED.

The conductivity of the thin film included in the comparison laminate A was 1.7×10⁻⁴

(Work Function)

A glass substrate having an ITO layer on one of the surfaces was prepared. Next, a coating film was formed on this glass substrate by a spin coating method using the dispersion liquid A described above. Thereafter, the coating film was baked at 150° C. to form a thin film. The thickness of the thin film was 130 nm.

As a result, a laminate including the glass substrate, the ITO layer, and the thin film was prepared. The obtained laminate is hereinafter referred to as an “evaluation laminate B”.

For comparison, a laminate was prepared according to a similar method using a commercially available dispersion liquid (manufactured by Avantama AG) in which ZnO nanoparticles were dispersed. The obtained laminate is hereinafter referred to as a “comparison laminate B”.

Next, according to the ultraviolet photoelectron spectroscopy, the work function of the thin film included in the evaluation laminate B was measured. The excitation light used in the ultraviolet photoelectron spectroscopy was HeI (21.2 eV).

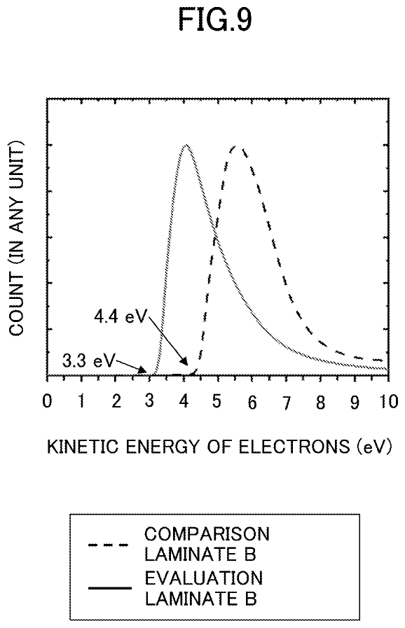

FIG. 9 illustrates a measurement result obtained with the evaluation laminate B. For comparison, FIG. 9 also illustrates a result obtained with the comparison laminate B.

As apparent from FIG. 9, the work function of the thin film in the evaluation laminate B was be 3.3 eV. The count peak in FIG. 9 is a distribution of kinetic energy of secondary electrons emitted from the sample in response to ultraviolet light irradiation, and the minimum value of the kinetic energy corresponds to the work function of the sample. When the feature of the peak on the low energy side (left side) is approximated by a straight line, the work function can be calculated from the intersection of the straight line and the X-axis.

With the comparison laminate B, the work function calculated in a similar manner was 4.4 eV. Therefore, the thin film of the evaluation laminate B can be said to have a significantly lower work function than the thin film constituted by ZnO nanoparticles.

### Example 2

According to a method similar to Example 1, a powdery material (hereinafter referred to as “powder B”) was produced. However, in this Example 2, the mixed gas used to rapidly cool the gas phase was a mixed gas in which N₂:O₂ was 60:40. Other production conditions are the same as those of Example 1.

Using the produced powder B, a dispersion liquid (hereinafter referred to as a “dispersion liquid B”) and a thin film-attached transparent substrate (hereinafter referred to as “a sample B with a thin film B”) were formed according to a method similar to Example 1. According to the method similar to Example 1, various evaluations were performed.

When the specific surface area was measured using the powder B, the specific surface area of the powder B was found to be 84.1 m²g⁻¹. The particle diameter of the powder B derived from the specific surface area was 12.3 nm. In contrast, an equivalent circular particle diameter R of the powder B derived from the method described above was about 10 nm.

It was also found that as a result of fluorescent X-ray analysis of the powder B, the cation ratio of the powder B was Zn:Si=77.8:22.2 in molar ratio.

Furthermore, it was found that the powder B and the thin film B include first particles (crystal phase containing ZnO) and second particles (amorphous phase containing SiO₄).

In an EDX mapping image, the abundance rate of the second particles was in a range of 40% to 60%.

Next, according to a method similar to Example 1, an evaluation laminate C was produced, and the conductivity was measured.

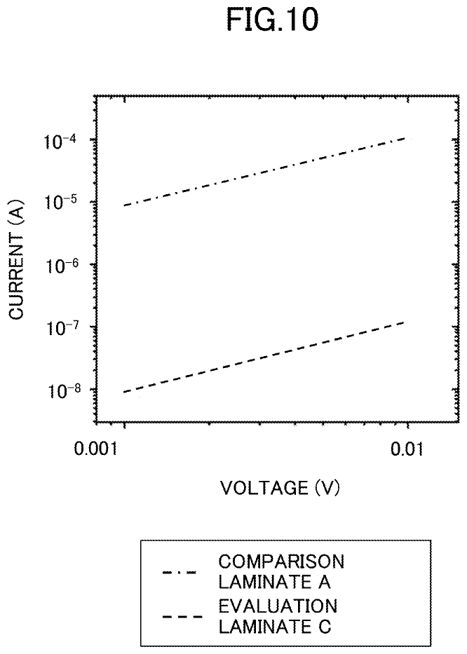

FIG. 10 illustrates a measurement result of the voltage-current relationship of the evaluation laminate C. For comparison, FIG. 10 also illustrates the result obtained with the comparison laminate A described above.

As apparent from FIG. 10, the thin film of the evaluation laminate C formed an ohmic contact with each of the Mo electrodes. When the conductivity of the thin film of the evaluation laminate C was calculated, the conductivity was found to be 4.6×10⁻⁸ Scm⁻¹.

Although the conductivity is slightly lower than the conductivity obtained with the evaluation laminate A described above, this conductivity can be said to be an adequate value, considering an application of the thin film of the evaluation laminate C to the electron injection layer, the electron transport layer, or both of the OLED.

### Example 3

(Preparation of Ink and Propylene Glycol Solvent)

Next, ink for inkjet printing was prepared using powder A.

Specifically, 0.714 g of the powder A described above was added to 27.875 g of propylene glycol, and furthermore, 100 g of zirconia beads with 0.3 mmφ serving as a crushing medium were mixed to prepare a mixture. Next, the mixture was put into a glass container, and dispersion processing was performed for 10 hours using a paint shaker device.

As a result, an ink (hereinafter referred to as an “ink A”) including ZSO nanoparticles at 2.5 mass % and propylene glycol at 97.5 mass % was obtained.

(Work Function)

A glass substrate having an ITO layer on one of the surfaces was prepared. Next, using an inkjet printer (Glass Jet manufactured by MICROJET Corporation), the ink A described above was discharged onto the substrate to form a droplet having a diameter of about 120 μm, and it was dried at room temperature. Similar droplets were arranged on the substrate to prepare a sample having a plurality of dot-shaped coating film having a diameter of about 120 μm on the substrate. Thereafter, the coating film was baked at 150° C.

As a result, a laminate including the glass substrate, the ITO layer, and the thin film was prepared. The obtained laminate is hereinafter referred to as an “evaluation laminate D”.

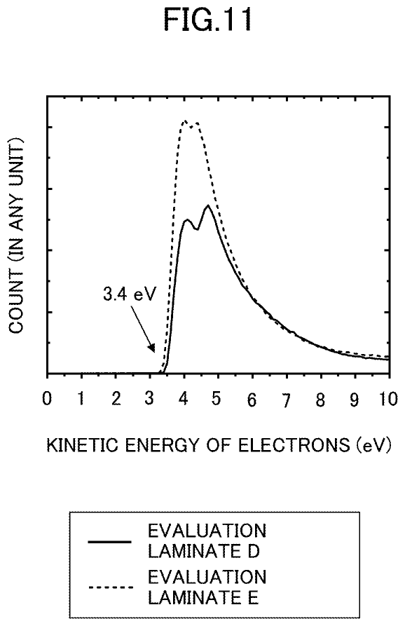

When the work function of the thin film in the evaluation laminate D was evaluated, it was found that the work function was 3.4 eV as illustrated in FIG. 11. It was found from above that the thin film including the ZSO nanoparticles with a small work function can be produced using an ink that can be printed by inkjet printing.

### Example 4

(Preparation of Ink and Addition of Dispersant)

As a dispersant, an ink was prepared according to the same method as that of Example 3 except that 0.536 g of DISPERBYK 190 was added. As a result, an ink (hereinafter referred to as an “ink B”) including a dispersant was obtained. According to a method similar to Example 3, a laminate including the glass substrate, the ITO layer, and the thin film was prepared. The obtained laminate is hereinafter referred to as an “evaluation laminate E”. When the work function of the thin film in the evaluation laminate E was evaluated, it was found that the work function was 3.4 eV as illustrated in FIG. 11. It was found from above that the thin film including the ZSO nanoparticles with a small work function can be produced even by applying the dispersant to the ink.

### Example 5

According to a method similar to Example 1, a powdery material (hereinafter referred to as “powder C”) was produced. However, in this Example 5, the mixed gas used to rapidly cool the gas phase was a mixed gas in which N₂:O₂ was 72:28. Other production conditions are the same as those of Example 1.

When the specific surface area was measured using the powder C, the specific surface area of the powder C was 108.9 m²g⁻¹. The particle diameter of the powder C derived from the specific surface area was 9.5 nm. In contrast, an equivalent circular particle diameter R of the powder C derived from the method described above was about 9 nm.

It was also found that as a result of fluorescent X-ray analysis of the powder C, the cation ratio of the powder C was Zn:Si=77.0:23.0 in molar ratio.

Furthermore, it was found that the powder C included first particles (crystal phase containing ZnO) and second particles (amorphous phase containing SiO₄). Based on the above, it was found from above that the particle diameters of the ZSO nanoparticles and the conductivity could be controlled by adjusting the oxygen concentration in the mixed gas used to rapidly cool the gas phase.

### Example 6

(Preparation of Ink and Ethylene Glycol Solvent)

Next, an ink for inkjet printing was prepared using the powder C.

Specifically, 0.714 g of the powder C described above was added to 27.875 g of ethylene glycol, and furthermore, 100 g of zirconia beads with 0.3 mmφ serving as a crushing medium were mixed to prepare a mixture. Next, the mixture was put into a glass container, and dispersion processing was performed for 10 hours using a paint shaker device.

As a result, an ink (hereinafter referred to as an “ink C”) including ZSO nanoparticles at 2.5 mass % and ethylene glycol at 97.5 mass % was obtained.

A glass substrate having an ITO layer on one of the surfaces was prepared. Furthermore, a bank of 60×200 μm was formed on the ITO film using the bank material. The depth of the bank was 1 μm. The ink C was discharged into the bank using an inkjet printer, and then dried at room temperature. Furthermore, using a hot plate, thermal treatment was performed at 150° C. Accordingly, the thin film including the ZSO nanoparticles was formed in the bank. The shape of the thin film was measured using a confocal laser scanning microscope VK-X manufactured by KEYENCE CORPORATION. The thickness of the thin film applied in the bank was 80 nm. The surface roughness of the thin film (surface roughness according to JIS B0601:2001) was about 10 nm.

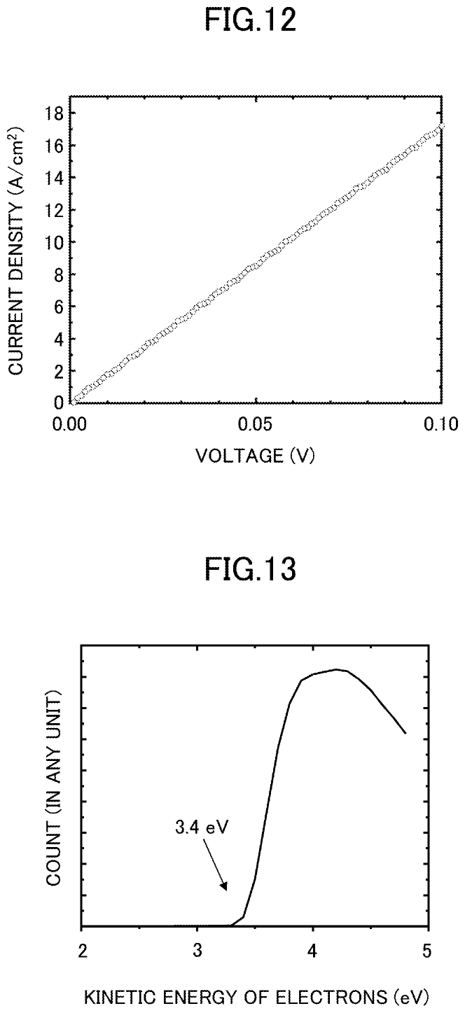

Furthermore, a Mo metal film was formed on the thin film by sputtering, and a laminate including the glass substrate, the ITO layer, the thin film, and the Mo metal layer was produced. The obtained laminate is hereinafter referred to as an “evaluation laminate F”. FIG. 12 illustrates the current density-voltage characteristics of the evaluation laminate F in a case where the Mo metal film was used as the cathode and the ITO layer was used as the anode. It was found that a voltage required to obtain, for example, 100 mA/cm² that is a current density sufficiently for driving the OLED, is 0.01 V or less, and the thin film exhibited a sufficient conductivity. It was found that the thin film including the Mo metal film and the ZSO nanoparticles was an ohmic contact.

According to a method similar to Example 3, a laminate including the glass substrate, the ITO layer, and the thin film was prepared using the ink C. The obtained laminate is hereinafter referred to as an “evaluation laminate G”. When the work function of the thin film in the evaluation laminate G was evaluated, it was found that the work function was 3.4 eV as illustrated in FIG. 13. It was found from above that the thin film including the ZSO nanoparticles with a small work function and a high conductivity can be produced by inkjet printing

What is claimed is:

1. An assembly of nanoparticles comprising metal oxide,
wherein the nanoparticles include zinc (Zn) and silicon (Si),
the nanoparticles have an atomic ratio of Zn/(Zn+Si) in a range of 0.3 to 0.95, and
the nanoparticles have an equivalent circular particle diameter in a range of 1 nm to 20 nm.

2. The assembly of nanoparticles according to claim 1, further comprising:
first nanoparticles including a crystal of zinc oxide (ZnO) in which silicon (Si) is dissolved; and
second nanoparticles in an amorphous state.

3. The assembly of nanoparticles according to claim 2, wherein the second nanoparticles include silicon dioxide.

4. The assembly of nanoparticles according to claim 2, wherein the second nanoparticles occupy 10% or more by volume with respect to the nanoparticles.

5. A dispersion liquid of nanoparticles in which the assembly of nanoparticles of claim 3 is dispersed.

6. An ink comprising:
a solvent;
a thickener; and
the assembly of nanoparticles of claim 3.

7. A thin film comprising the assembly of nanoparticles of claim 3.

8. The thin film according to claim 7, wherein the thin film has a work function of 3.5 eV or less, and a conductivity of 10⁻⁸ Scm⁻¹ or more.

9. An organic light emitting diode (OLED) comprising:
a first electrode;
an organic light emitting layer; and
an additional layer provided between the first electrode and the organic light emitting layer,
wherein the additional layer is constituted by the thin film according to claim 7.

10. A method for producing an assembly of nanoparticles including metal oxide, the production method comprising:
preparing a source material including at least one selected from the group consisting of zinc, silicon, zinc oxide, silicon dioxide, and zinc silicate, the source material including both of a zinc-based component and a silicon-based component;
processing the source material with thermal plasma under a first oxygen-containing atmosphere of which a content of oxygen is 0.001% to 90% in volume ratio to vaporize the source material; and
solidifying the vaporized source material under a second oxygen-containing atmosphere of which a content of oxygen is 0.00001% to 90% in volume ratio.

11. The method according to claim 10, wherein the preparation of the source material further comprises preparing the source material having an atomic ratio of Zn/(Zn+Si) in a range of 0.3 to 0.95.

12. The method according to claim 10, wherein the preparation of the source material comprises preparing a slurry including zinc oxide particles and silicon oxide particles as the source material.
